(19) United States
(12) Patent Application Publication
(10) Pub. No.: US 2026/0247987 A1
(43) Pub. Date: Aug. 20, 2026

(54) SEMICONDUCTOR DEVICE AND METHOD FOR MANUFACTURING THE SAME

(71) Applicant: Samsung Electronics Co., Ltd., Suwon-si (KR)

(72) Inventors: Seung Kyo Lee, Suwon-si (KR); Min-Cheol Kwak, Suwon-si (KR); Nam Ho Kim, Suwon-si (KR)

(73) Assignee: Samsung Electronics Co., Ltd., Suwon-si (KR)

(21) Appl. No.: 19/328,005

(22) Filed: Sep. 12, 2025

(30) Foreign Application Priority Data
Feb. 14, 2025 (KR) 10-2025-0019645

(51) Int. Cl. H01L 23/544

(52) U.S. Cl. CPC H10W 46/00; H10W 46/301

(57) ABSTRACT

Provided is a semiconductor device. The semiconductor device includes a chip area and a scribe lane area, a first substrate structure disposed in the scribe lane area and including a first key pattern structure, a second substrate structure disposed in the scribe lane area and disposed on the first substrate structure, wherein the second substrate structure includes a second key pattern structure, and a blocking pattern structure disposed in the scribe lane area and composed of different materials, wherein the blocking pattern structure is disposed between the first key pattern structure and the second key pattern structure in a vertical direction.

### CROSS-REFERENCE TO RELATED APPLICATIONS

The present application claims priority to and the benefit under 35 U.S.C. § 119(a)-(d) of Korean Patent Application No. 10-2025-0019645, filed on Feb. 14, 2025 in the Korean Intellectual Property Office, the entire disclosure of which is incorporated herein by reference.

### FIELD

The present disclosure relates to a semiconductor device and a method for manufacturing the same.

### BACKGROUND

Recently, as an electronic device becomes faster and consumes a smaller amount of power, a semiconductor device embedded therein is also required to have a fast operating speed and/or a low operating voltage. In order to meet these required characteristics, the semiconductor device may be more highly integrated.

As the semiconductor device becomes highly integrated, a multi-bonding process of bonding a plurality of wafers to one another a plurality of times may be performed. In addition, the number of alignment keys and/or overlay keys required in such a multi-bonding process is also increasing.

### SUMMARY

A technical purpose to be achieved by the present disclosure is to provide a semiconductor device capable of preventing incorrect measurement due to signal superimposition in a process for measuring alignment keys and/or overlay keys.

Another technical purpose to be achieved by the present disclosure is to provide a method for manufacturing a semiconductor device capable of preventing incorrect measurement due to signal superimposition in a process for measuring alignment keys and/or overlay keys.

A semiconductor device according to some embodiments of the present disclosure includes a chip area and a scribe lane area, a first substrate structure disposed in the scribe lane area and including a first key pattern structure, a second substrate structure disposed in the scribe lane area and disposed on the first substrate structure, wherein the second substrate structure includes a second key pattern structure, and a blocking pattern structure disposed in the scribe lane area and composed of different materials, wherein the blocking pattern structure is disposed between the first key pattern structure and the second key pattern structure in a vertical direction.

A semiconductor device according to some embodiments of the present disclosure includes a chip area and a scribe lane area, a first substrate structure disposed in the scribe lane area and including a first key pattern structure, a blocking pattern structure disposed in a recess defined in the first substrate structure, wherein the blocking pattern structure includes a first pattern layer and a second pattern layer including different materials and sequentially stacked, and a second substrate structure disposed in the scribe lane area and disposed on the first substrate structure, wherein the second substrate structure includes a second key pattern structure, wherein the first key pattern structure, the second key pattern structure, and the blocking pattern structure overlap one another in a vertical direction.

A semiconductor device according to some embodiments of the present disclosure includes a first area including a memory cell, a second area disposed around the first area and including a key pattern structure, wherein the memory cell includes word lines extending in the first direction, a bit line extending in a second direction intersecting the first direction, and an active area connected to the bit line, wherein the key pattern structure includes, a first key pattern structure, a second key pattern structure disposed on the first key pattern structure, and a blocking pattern structure composed of different materials and disposed between the first key pattern structure and the second key pattern structure in a vertical direction.

Some embodiments of the disclosure relate to a method of manufacturing a semiconductor device comprising: providing a chip area and a scribe lane area; disposing in the scribe lane area a first substrate structure having a first key pattern structure; disposing in the scribe lane area and on the first substrate structure, a second substrate structure having a second key pattern structure; and disposing in the scribe lane area between the first key pattern structure and second key pattern structure in a vertical direction, a blocking pattern structure composed of different materials.

The technical purposes of the present disclosure are not limited to the technical purposes mentioned above, and other technical purposes not mentioned may be clearly understood by those skilled in the art from the following description.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is a view schematically illustrating a wafer on which semiconductor devices according to some embodiments are formed;

FIG. 2 is an enlarged view of a portion P of FIG. 1;

FIG. 3 is a cross-sectional view illustrating the process monitoring structure of FIG. 2;

FIGS. 4 to 6 are cross-sectional views illustrating a semiconductor device according to some embodiments;

FIG. 7 is a schematic plan view of a semiconductor device according to some embodiments;

FIGS. 8 to 17 are diagrams of intermediate structures corresponding to intermediate steps of a method for manufacturing a semiconductor device according to some embodiments;

FIG. 18 is an example diagram for illustrating a semiconductor device according to some embodiments;

FIG. 19 is an example diagram for illustrating a semiconductor device according to some embodiments.

### DETAILED DESCRIPTION

Hereinafter, embodiments according to the technical idea of the present disclosure will be described with reference to the accompanying drawings.

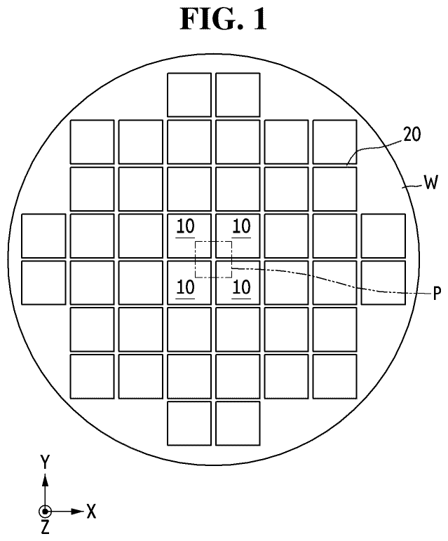

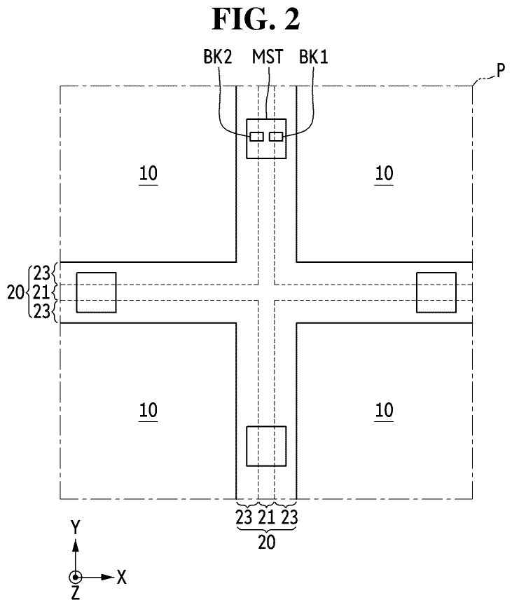

FIG. 1 is a view schematically illustrating a wafer on which semiconductor devices according to some embodiments are formed. FIG. 2 is an enlarged view of a portion P of FIG. 1.

Referring to FIGS. 1 and 2, the wafer W may include chip areas 10 in which semiconductor integrated circuits are located and a scribe lane area 20 between the chip areas 10. The wafer W may be a semiconductor substrate, for example, one of a silicon substrate, a germanium substrate, and a silicon-germanium substrate.

The chip areas 10 may be two-dimensionally arranged along a first direction Y and a second direction X intersecting (e.g., orthogonal to) the first direction Y. Each of the first and second directions Y and X may be parallel to an upper surface and/or a lower surface of the wafer W. Each of the chip areas 10 may be surrounded with the scribe lane area 20.

The scribe lane area 20 may include a plurality of first scribe lane areas SL1 extending in the first direction Y and a plurality of second scribe lane areas SL2 intersecting the first scribe lane areas SL1 and extending in the second direction X. The scribe lane area 20 may include a cutting area 21 cut by a sawing or dicing machine and edge areas 23 between the cutting area 21 and the chip areas 10. The edge areas 23 may surround the chip areas 10, respectively. For example, in a plan view, the cutting area 21 may be interposed between adjacent ones of the chip areas 10, and the edge areas 23 may be interposed between the chip areas 10 and the cutting area 21.

The semiconductor devices may be provided on the chip areas 10 of the wafer W. For example, the semiconductor memory elements such as a dynamic random access memory (DRAM), a static random access memory (SRAM), a flash memory (NAND), and a resistive random access memory (RRAM) may be provided on the chip areas 10. In another example, a processor such as a micro electro mechanical systems (MEMS) element, an optoelectronic element, a CPU, or a DSP may be provided on the chip areas 10. In still another example, standard cells including semiconductor devices such as an OR gate or an AND gate may be provided on the chip areas 10 of the wafer W.

A process monitoring structure MST may be provided on the scribe lane area 20 of the wafer W. The process monitoring structure MST may be monitoring patterns for monitoring whether manufacturing processes (e.g., a patterning process, etc.) of the semiconductor device are properly performed. For example, the process monitoring structure MST may include monitoring patterns such as alignment patterns serving as alignment references related to a position where a pattern is formed, overlay patterns for checking an overlap state between upper and lower patterns, or measurement patterns for measuring a thickness and a line width of the patterns. The process monitoring structure MST may be located on the cutting area 21 and the edge areas 23.

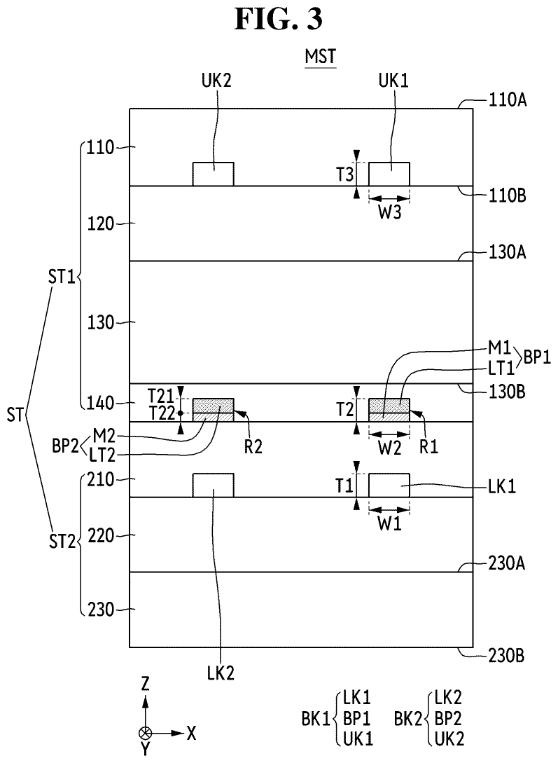

FIG. 3 is a cross-sectional view illustrating the process monitoring structure of FIG. 2. Hereinafter, a key pattern structure and a blocking pattern structure of the process monitoring structure will be described in detail with reference to FIG. 3.

Referring to FIG. 3, the process monitoring structure MST according to some embodiments may include a bonding key structure BK1 and BK2. The bonding key structure BK1 and BK2 may include a first key pattern structure UK1 and UK2, a second key pattern structure LK1 and LK2, and a blocking pattern structure BP1 and BP2.

At least a portion of the bonding key structure BK1 and BK2 may be disposed in the edge areas 23 (see FIG. 2) of the scribe lane area 20 (see FIG. 2).

Each of the first key pattern structure UK1 and UK2, the second key pattern structure LK1 and LK2, and the blocking pattern structure BP1 and BP2 may include a plurality of patterns. Although FIG. 3 illustrates that each of the first key pattern structure UK1 and UK2, the second key pattern structure LK1 and LK2, and the blocking pattern structure BP1 and BP2 includes two patterns, the number of patterns of each of the first key pattern structure UK1 and UK2, the second key pattern structure LK1 and LK2, and the blocking pattern structure BP1 and BP2 is not limited thereto.

The bonding structure ST may include a first substrate structure ST1 and a second substrate structure ST2 stacked in the third direction Z.

The first substrate structure ST1 may include a first substrate 110, a first interlayer insulating film 120, a second substrate 130, and a buffer layer 140. The first key pattern structure UK1 and UK2 and the blocking pattern structure BP1 and BP2 may be disposed in the first substrate structure ST1.

The first substrate 110 may be, for example, a silicon substrate, a gallium arsenide substrate, a silicon germanium substrate, a ceramic substrate, a quartz substrate, or a glass substrate for display, or may be a semiconductor on insulator (SOI) substrate. However, embodiments of the present disclosure are not limited thereto. The first substrate 110 may be provided as a handling substrate (e.g., a wafer).

The first substrate 110 may include a first surface 110A and a second surface 110B facing one another. The first surface 110A and the second surface 110B may extend in parallel to each of the first and second directions Y and X. In some embodiments, the third direction Z may mean a height direction perpendicular to each of the first surface 110a and the second surface 110B.

The first key pattern structure UK1 and UK2 may be disposed in the first substrate 110. At least a portion of the first key pattern structure UK1 and UK2 may be disposed in the edge areas 23 (see FIG. 2) of the scribe lane area 20 (see FIG. 2).

Although not shown specifically, the first substrate 110 may include a plurality of conductive layers and insulating layers. For example, the first key pattern structure UK1 and UK2 may be formed using at least one of a conductive layer and an insulating layer in the first substrate 110. The first key pattern structure UK1 and UK2 may include an insulating material and/or a conductive material.

A thickness in the third direction Z of the first key pattern structure UK1 and UK2 is not limited to that illustrated in FIG. 3. The thickness in the third direction Z of the first key pattern structure UK1 and UK2 may vary depending on the layer.

The first interlayer insulating film 120 may be formed between the second surface 110B of the first substrate 110 and a first surface 130A of a second substrate 130 to be described later. Although not specifically shown, the first interlayer insulating film 120 may include a plurality of conductive layers and insulating layers. Adjacent ones of the plurality of conductive layers may be electrically spaced apart from one another via each of the insulating layers.

The first interlayer insulating film 120 may include, for example, silicon oxide, silicon oxynitride, a low-k material having a lower dielectric constant than that of silicon oxide, or a combination thereof. However, embodiments of the present disclosure are not limited thereto.

The second substrate 130 may be made of bulk silicon or silicon-on-insulator (SOI). The second substrate 130 may be a silicon substrate, or may include a material other than silicon, such as silicon germanium, silicon germanium on insulator (SGOI), indium antimonide, lead telluride compound, indium arsenide, indium phosphide, gallium arsenide, or gallium antimonide. Although not shown specifically, peripheral circuit elements electrically connected to the semiconductor memory elements of the chip areas 10 of FIG. 1 may be formed on the second substrate 130.

The second substrate 130 may include the first surface 130A and a second surface 130B facing one another. Although not specifically shown, the second substrate 130 may include a plurality of conductive layers and insulating layers. The plurality of conductive layers may be electrically connected to the peripheral circuit element.

The buffer layer 140 may be formed between the second surface 130B of the second substrate 130 and the second substrate structure ST2. The buffer layer 140 may include, for example, silicon oxide, silicon oxynitride, a low-k material having a lower dielectric constant than that of silicon oxide, or a combination thereof. However, embodiments of the present disclosure are not limited thereto.

The blocking pattern structure BP1 and BP2 may be disposed in the buffer layer 140. At least a portion of the blocking pattern structure BP1 and BP2 may be disposed in the edge area 23 (see FIG. 2) of the scribe lane area 20 (see FIG. 2).

The second substrate structure ST2 may include a third substrate 230, a second interlayer insulating film 220, and a third interlayer insulating film 210. The second key pattern structure LK1 and LK2 may be disposed in the second substrate structure ST2.

The third substrate 230 may be made of bulk silicon or silicon-on-insulator (SOI). The second substrate 230 may be a silicon substrate, or may include a material other than silicon, such as silicon germanium, silicon germanium on insulator (SGOI), indium antimonide, lead telluride compound, indium arsenide, indium phosphide, gallium arsenide, or gallium antimonide. Although not shown specifically, the semiconductor memory elements of the chip areas 10 (see FIG. 1) may be formed on the third substrate 230.

The third substrate 230 may include a first surface 230A and a second surface 230B facing one another. Although not specifically shown, the third substrate 230 may include a plurality of conductive layers and insulating layers. The plurality of conductive layers may be electrically connected to the semiconductor memory element.

The second interlayer insulating film 220 may be formed between the first surface 230A of the third substrate 230 and the third interlayer insulating film 210 to be described later. Although not specifically shown, the second interlayer insulating film 220 may include a plurality of conductive layers and insulating layers. Adjacent ones of the plurality of conductive layers may be electrically spaced apart from one another via each of the insulating layers.

The second interlayer insulating film 220 may include, for example, silicon oxide, silicon oxynitride, a low-k material having a lower dielectric constant than that of silicon oxide, or a combination thereof. However, embodiments of the present disclosure are not limited thereto.

The third interlayer insulating film 210 may be formed between the buffer layer 140 and the second interlayer insulating film 220. Although not shown specifically, the third interlayer insulating film 210 may include a plurality of conductive layers and insulating layers. Adjacent ones of the plurality of conductive layers may be electrically spaced apart from one another via each of the insulating layers.

The third interlayer insulating film 210 may include, for example, silicon oxide, silicon oxynitride, a low-k material having a lower dielectric constant than that of silicon oxide, or a combination thereof. However, embodiments of the present disclosure are not limited thereto.

Although FIG. 3 illustrates that the second substrate structure ST2 includes two interlayer insulating films 210 and 220, the number of interlayer insulating films included in the second substrate structure ST2 is not limited thereto. In one example, there may be no boundary surface between the second interlayer insulating film 220 and the third interlayer insulating film 210.

In addition, although FIG. 3 illustrates that the second key pattern structure LK1 and LK2 is disposed only in the third interlayer insulating film 210, embodiments of the present disclosure are not limited thereto. Unlike the illustrated example, the second key pattern structure LK1 and LK2 may be disposed in the second interlayer insulating film 220.

At least a portion of the second key pattern structure LK1 and LK2 may be disposed in the edge areas 23 of FIG. 2 of the scribe lane area 20 of FIG. 2. The second key pattern structure LK1 and LK2 may be formed using at least one of a conductive layer and an insulating layer in the third interlayer insulating film 210. The second key pattern structure LK1 and LK2 may include an insulating material and/or a conductive material.

A thickness in the third direction Z of the second key pattern structure LK1 and LK2 is not limited to that illustrated in FIG. 3. The thickness in the third direction Z of the second key pattern structure LK1 and LK2 may vary based on the layer.

For example, the thickness in the third direction Z of each of the first key pattern structure UK1 and UK2 and the second key pattern structure LK1 and LK2 may be greater than the thickness in the third direction Z of the blocking pattern structure BP1 and BP2, unlike that illustrated in FIG. 3.

In the third direction Z, the blocking pattern structure BP1 and BP2 may be disposed between the first key pattern structure UK1 and UK2 and the second key pattern structure LK1 and LK2.

The first key pattern structure UK1 and UK2, the second key pattern structure LK1 and LK2, and the blocking pattern structure BP1 and BP2 may overlap one another in the third direction Z. That is, the first key pattern structure UK1 and UK2, the second key pattern structure LK1 and LK2, and the blocking pattern structure BP1 and BP2 may be disposed at the same position in each of the first horizontal direction X and the second horizontal direction Y.

Accordingly, a width W3 of the first key pattern structure UK1 and UK2, a width W1 of the second key pattern structure LK1 and LK2, and a width W2 of the blocking pattern structure BP1 and BP2 may be equal to one another. In addition, for example, each of the thickness T3 of the first key pattern structure UK1 and UK2 and the thickness T1 of the second key pattern structure LK1 and LK2 may be equal to the thickness T2 of the blocking pattern structure BP1 and BP2. However, the technical idea of embodiments of the present disclosure are not limited thereto, and each of the thickness T3 of the first key pattern structure UK1 and UK2 and the thickness T1 of the second key pattern structure LK1 and LK2 may be greater than the thickness T2 of the blocking pattern structure BP1 and BP2.

The blocking pattern structure BP1 and BP2 may include a first pattern layer LT1 and LT2 and a second pattern layer M1 and M2 sequentially stacked in the third direction Z. The blocking pattern structure BP1 and BP2 may be disposed in a recess R1 and R2 of the third interlayer insulating film 210.

The first pattern layer LT1 and LT2 may be in contact with each of a bottom surface and a sidewall of the recess R1 and R2. The second pattern layer M1 and M2 may be disposed on the first pattern layer LT1 and LT2 and in the recess R1 and R2.

A thickness T21 in the third direction Z of the first pattern layer LT1 and LT2 may be greater than a thickness T22 in the third direction Z of the second pattern layer M1 and M2. For example, the thickness T21 of the first pattern layer LT1 and LT2 may be in a range of 2000 angstroms or greater, and the thickness T22 of the second pattern layer M1 and M2 may be in a range of 500 angstroms or greater. However, embodiments of the present disclosure are not limited thereto.

The first pattern layer LT1 and LT2 and the second pattern layer M1 and M2 may include different materials from one another. For example, the first pattern layer LT1 and LT2 may include amorphous carbon, and the second pattern layer M1 and M2 may include a metal such as tungsten (W). However, the materials of the first pattern layer LT1 and LT2 and the second pattern layer M1 and M2 are not limited thereto.

For example, the first pattern layer LT1 and LT2 may have a transmittance of light in a wavelength range of 400 nm to 900 nm in a range of 25% or smaller. For example, the second pattern layer M1 and M2 may have a transmittance of light in a wavelength range of 400 nm to 900 nm in a range of 10% or smaller. For example, the blocking pattern structure BK1 and BK2 may have a transmittance of light in a wavelength range of 400 nm to 900 nm in a range of 5% or smaller. However, the technical idea of embodiments of the present disclosure are not limited thereto.

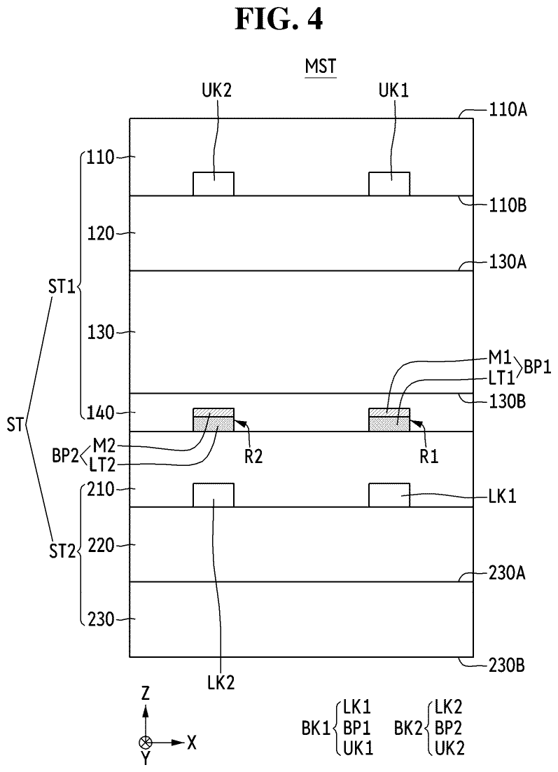

FIGS. 4 to 6 are cross-sectional views illustrating a semiconductor device according to some embodiments. For convenience of description, contents duplicate with those described above with reference to FIGS. 1 to 3 will be briefly described or descriptions thereof will be omitted.

Referring to FIG. 4, the second pattern layer M1 and M2 may be in contact with the bottom surface and the sidewall of the recess R1 and R2, and the first pattern layer LT1 and LT2 may be disposed on the second pattern layer M1 and M2 and in the recess R1 and R2. The first pattern layer LT1 and LT2 may include carbon (C), and the second pattern layer M1 and M2 may include a metal such as tungsten (W). However, the materials of the first and second pattern layer are not limited thereto.

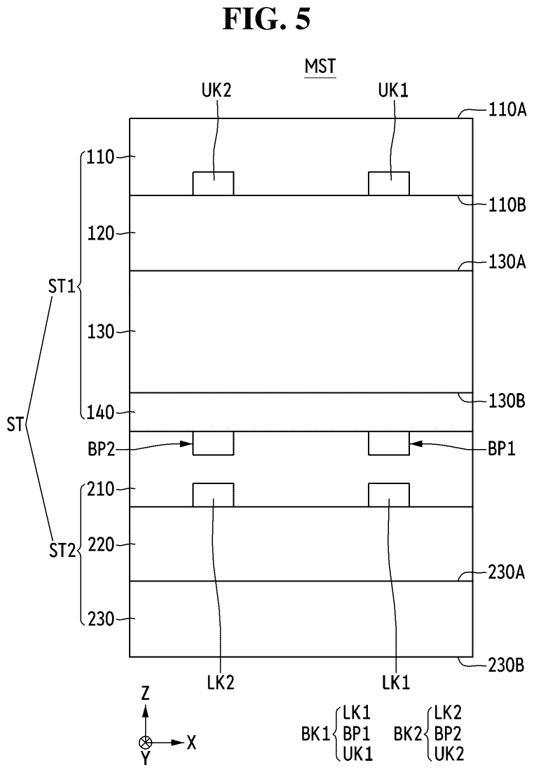

Referring to FIG. 5, the blocking pattern structure BP1 and BP2 may be disposed in the second substrate structure ST2. The blocking pattern structure BP1 and BP2 may include a third pattern layer (not shown) and a fourth pattern layer (not shown), which are sequentially stacked. The third pattern layer (not shown) and the fourth pattern layer (not shown) may include different materials. For example, the third pattern layer may include carbon (C), and the fourth pattern layer may include a metal such as tungsten (W).

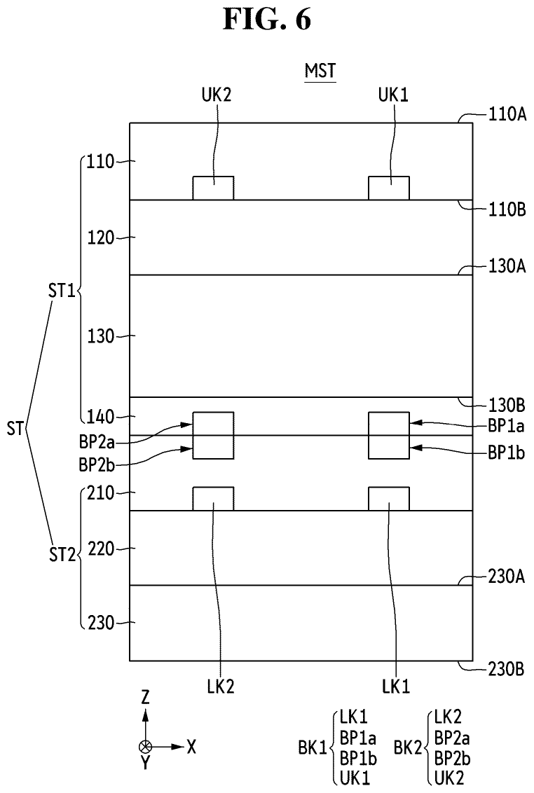

Referring to FIG. 6, the blocking pattern structure BP1 and BP2 may be disposed in each of the first and second substrate structures ST1 and ST2. The blocking pattern structure BP1 and BP2 may include first and second blocking patterns BP1a and BP2a in the first substrate structure ST1 and third and fourth blocking patterns BP1b and BP2b in the second substrate structure ST2. The first and second blocking patterns BP1a and BP2a may include a carbon-based material and a metal material having low transmittance in a specific wavelength. The third and fourth blocking patterns BP1b and BP2b may include a carbon-based material and a metal material having low transmittance in a specific wavelength.

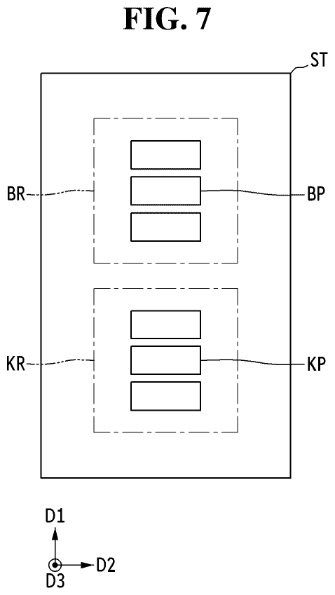

FIG. 7 is a schematic plan view of a semiconductor device according to some embodiments. For convenience of description, contents duplicate with those described above with reference to FIGS. 1 to 6 will be briefly described or descriptions thereof will be omitted.

Referring to FIG. 7, the bonding structure ST according to some embodiments may extend in each of first and second horizontal directions D1 and D2 intersecting one another in a plan view. A vertical direction D3 may mean a height direction perpendicular to each of the first and second horizontal directions D1 and D2.

For example, the first and second horizontal directions D1 and D2 of FIG. 7 may correspond to the first and second directions Y and X of FIGS. 1 to 6, respectively, and the vertical direction D3 of FIG. 7 may correspond to the third direction Z of FIGS. 1 to 6. However, embodiments of the present disclosure are not limited thereto. For example, the first and second horizontal directions D1 and D2 of FIG. 7 may correspond to the second and first directions X and Y of FIGS. 1 to 6, respectively.

The bonding structure ST may include a first area BR and a second area KR spaced apart from one another. The first area BR may be an area in which the blocking pattern BP is disposed. The blocking pattern BP of FIG. 7 may correspond to the blocking pattern structure BP1 and BP2 of FIGS. 1 to 6. The second area KR may be an area in which a peripheral key pattern KP different from the blocking pattern BP is disposed. The peripheral key pattern KP of FIG. 7 may be a pattern other than the first key pattern structure UK1 and UK2, the second key pattern structure LK1 and LK2, and the blocking pattern structure BP1 and BP2 of FIGS. 1 to 6. The peripheral key pattern KP may be a pattern other than the process monitoring structure MST on the scribe lane area 20. For example, a portion of the peripheral key pattern KP may be formed in a peripheral portion of the process monitoring structure MST. However, embodiments of the present disclosure are not limited thereto.

In a plan view, the first area BR and the second area KR may be spaced apart from one another. For example, the first area BR and the second area KR may be spaced apart from one another in the first horizontal direction D1. However, embodiments of the present disclosure are not limited thereto.

For example, the first area BR in which the blocking pattern BP is disposed and the second area KR in which the peripheral key pattern KP is disposed may be formed in different areas. In this case, the blocking patterns BP formed in a separate opening process may be disposed in a specific area, thereby reducing difficulty of the process.

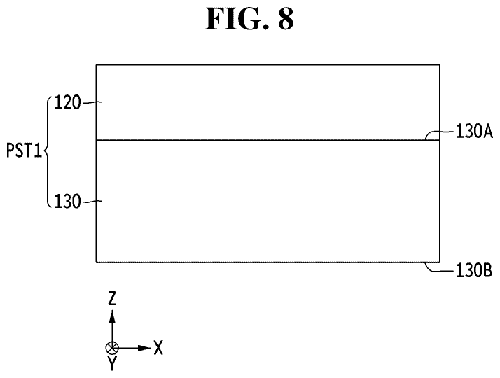

FIGS. 8 to 17 are diagrams of intermediate structures corresponding to intermediate steps of a method for manufacturing a semiconductor device according to some embodiments. For convenience of description, contents duplicate with those described above with reference to FIGS. 1 to 7 will be briefly described or descriptions thereof will be omitted.

Referring to FIG. 8, a pre-first stack structure PST1 including the peripheral circuit substrate 130 and the first interlayer insulating film 120 may be formed. The first interlayer insulating film 120 may be formed on the peripheral circuit substrate 130.

The peripheral circuit substrate 130 may be made of, for example, bulk silicon or silicon-on-insulator (SOI). However, embodiments of the present disclosure are not limited thereto. Although not shown specifically, the peripheral circuit elements electrically connected to the semiconductor memory elements of the chip areas 10 (see FIG. 1) may be formed in the peripheral circuit substrate 130. The peripheral circuit substrate 130 may include a first surface 130A and a second surface 130B facing one another.

The first interlayer insulating film 120 may be formed on the first surface 130A of the peripheral circuit substrate 130. Although not specifically shown, the first interlayer insulating film 120 may include a plurality of conductive layers and insulating layers. The first interlayer insulating film 120 may include, for example, silicon oxide, silicon oxynitride, a low-k material having a lower dielectric constant than that of silicon oxide, or a combination thereof. However, embodiments of the present disclosure are not limited thereto.

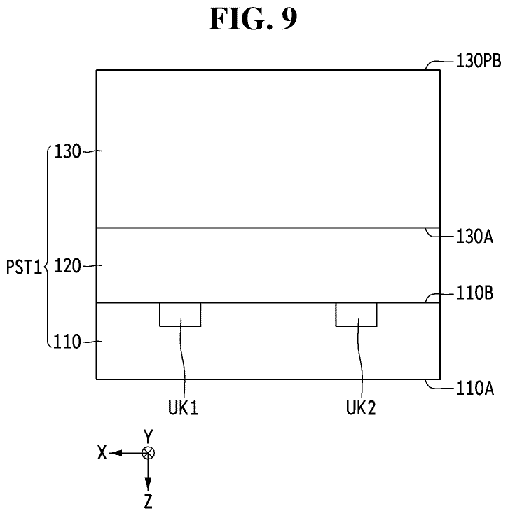

Referring to FIG. 9, after the pre-first stack structure PST1 of FIG. 8 has been turned upside down, the handling substrate 110 may be bonded to the pre-first stack structure PST1. Accordingly, the pre-first stack structure PST1 may include the handling substrate 110, the first interlayer insulating film 120, and the peripheral circuit substrate 130. The handling substrate 110 on which the first key pattern structure UK1 and UK2 has been disposed may be formed on the first interlayer insulating film 120. The handling substrate 110 may include the first surface 110A and the second surface 110B facing one another.

The first key pattern structure UK1 and UK2 may be disposed closer to the second surface 110B than to the first surface 110A of the handling substrate 110. However, embodiments of the present disclosure are not limited thereto. The first key pattern structure UK1 and UK2 may be formed using at least one of a conductive layer and an insulating layer in the handling substrate 110. The first key pattern structure UK1 and UK2 may include an insulating material and/or a conductive material.

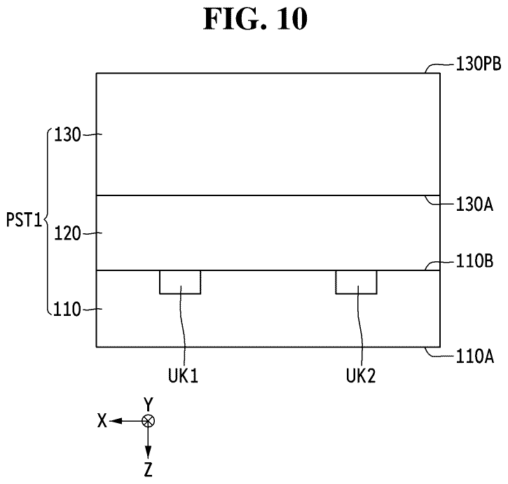

Referring to FIG. 10, at least a portion of the peripheral circuit substrate 130 may be removed from the second surface 130PB of the peripheral circuit substrate 130. Accordingly, a thickness in the third direction Z of the peripheral circuit substrate 130 may be reduced. Thus, the peripheral circuit substrate 130 may include the first surface 130A and a third surface 130B facing one another.

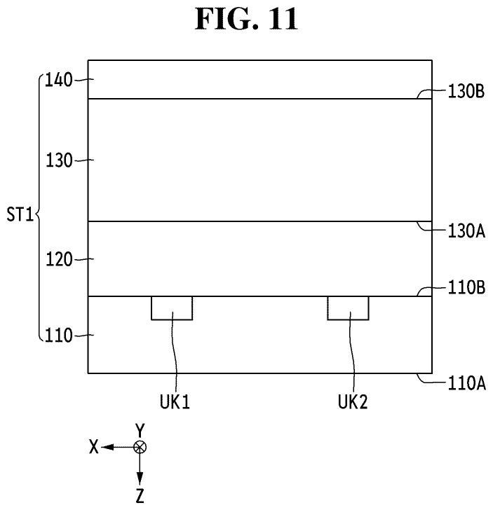

Referring to FIG. 11, the buffer layer 140 may be further formed in the first stack structure ST1 of FIG. 10. Accordingly, the first stack structure ST1 including the handling substrate 110, the first interlayer insulating film 120, the peripheral circuit substrate 130, and the buffer layer 140 may be formed.

The buffer layer 140 may be formed on the third surface 130B of the peripheral circuit substrate 130. The buffer layer 140 may include, for example, silicon oxide, silicon oxynitride, a low-k material having a lower dielectric constant than that of silicon oxide, or a combination thereof. However, embodiments of the present disclosure are not limited thereto.

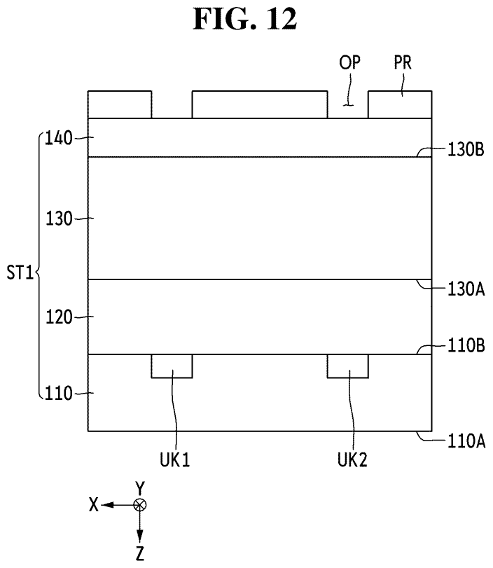

Referring to FIG. 12, a photoresist pattern PR may be formed on the buffer layer 140. The photoresist pattern PR may have an opening OP defined therein corresponding to and overlapping the first key patterns UK1 and UK2. A width of the opening OP in each of the first direction Y and the second direction X may be equal to a width of the first key pattern UK1 and UK2 in each of the first direction Y and the second direction X.

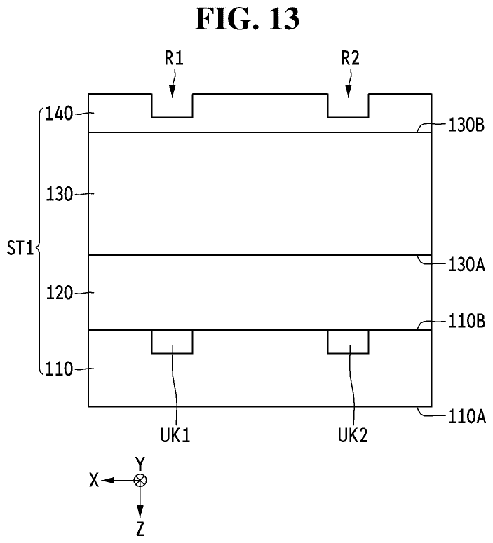

Referring to FIG. 13, the recess R1 and R2 may be formed in the buffer layer 140 using the photoresist pattern PR of FIG. 12. The recess R1 and R2 may extend into at least a portion of the buffer layer 140 in the third direction Z. A width of the recess R1 and R2 in each of the first direction Y and the second direction X may be equal to the width of the first key pattern UK1 and UK2 in each of the first direction Y and the second direction X. Thereafter, the photoresist pattern PR may be removed.

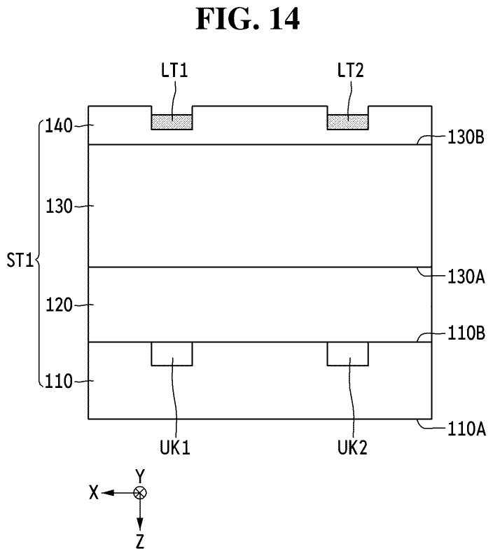

Referring to FIG. 14, the first pattern layer LT1 and LT2 may be formed on the bottom surface and the sidewall of the recess R1 and R2. The first pattern layer LT1 and LT2 may be in contact with the bottom surface and a portion of the sidewall of the recess R1 and R2. The first pattern layer LT1 and LT2 may be formed in a portion of the recess R1 and R2 in the third direction Z.

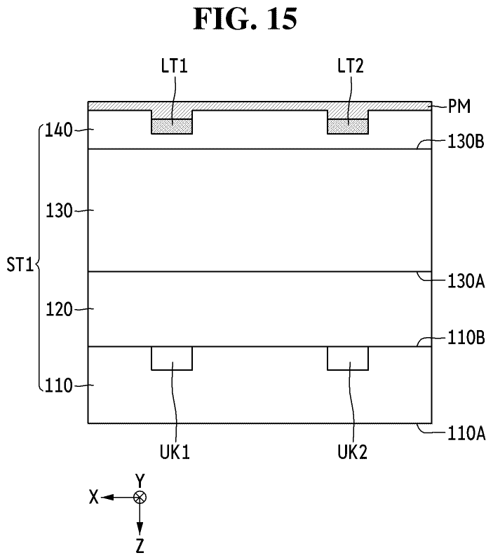

Referring to FIG. 15, a pre-metal layer PM may be formed on the first pattern layer LT1 and LT2. The pre-metal layer PM may be formed in a portion of the recess R1 and R2 remaining after the recess has been filled with the first pattern layer LT1 and LT2 and on an upper surface of the buffer layer 140.

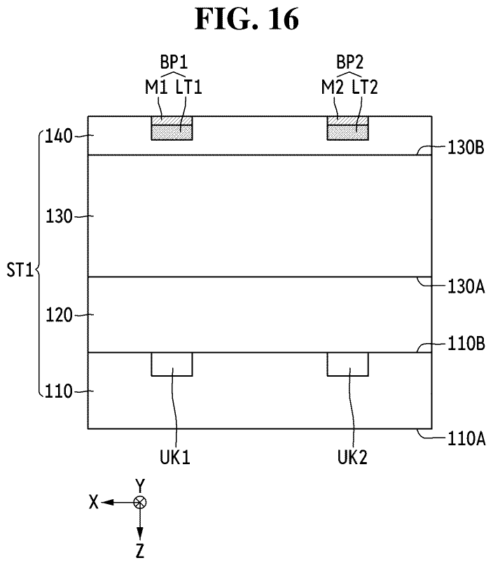

Referring to FIG. 16, a planarization process may be performed on the upper surface of the buffer layer 140 such that the upper surface of the second pattern layer M1 and M2 and the upper surface of the buffer layer 140 are coplanar with one another. Accordingly, the second key pattern BP1 and BP2 in which the first pattern layer LT1 and LT2 and the second pattern layer M1 and M2 are sequentially stacked may be formed. For example, the planarization process may include removing at least a portion of the pre-metal layer PM using chemical mechanical polishing (CMP). However, embodiments of the present disclosure are not limited thereto.

A thicknesses in the third direction Z of the first pattern layer LT1 and LT2 may be greater than the thickness in the third direction Z of the second pattern layer M1 and M2. For example, the thickness T21 of the first pattern layer LT1 and LT2 may be 2000 angstroms or greater, and the thickness T22 of the second pattern layer M1 and M2 may be 500 angstroms or greater. However, embodiments of the present disclosure are not limited thereto.

For example, the first pattern layer LT1 and LT2 may include amorphous carbon (C), and the second pattern layer M1 and M2 may include a metal such as tungsten (W).

For example, the first pattern layer LT1 and LT2 may have the transmittance of light in the wavelength range of 400 nm to 900 nm in a range of 25% or smaller. For example, the second pattern layer M1 and M2 may have the transmittance of the light of the wavelength band of 400 nm to 900 nm in a range of 10% or smaller. For example, the blocking pattern structure BK1 and BK2 including both the first pattern layer LT1 and LT2 and the second pattern layer M1 and M2 may have the transmittance of the light of the wavelength band of 400 nm to 900 nm in a range of 5% or smaller.

The light of the wavelength band used in a process for measuring the alignment keys and/or the overlay keys may not reach a layer in which the second key pattern structure LK1 and LK2 are present, due to the blocking pattern structure BP1 and BP2. This may prevent incorrect measurement due to signal superimposition in the process for measuring the alignment keys and/or the overlay keys.

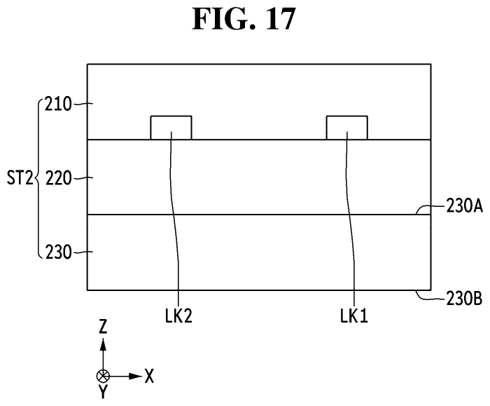

Referring to FIG. 17, the second stack structure ST2 may be formed. The second stack structure ST2 may include the substrate 230, the second interlayer insulating film 220, and the third interlayer insulating film 210.

The substrate 230 may be made of, for example, bulk silicon or silicon-on-insulator (SOI). However, embodiments of the present disclosure are not limited thereto. Although not specifically illustrated, the semiconductor memory elements of the chip areas 10 (see FIG. 1) may be formed in the substrate 230.

The substrate 230 may include a first surface 230A and a second surface 230B facing one another. The third key patterns LK1 and LK2 may be disposed on the first surface 230A.

The second interlayer insulating film 220 may be formed between the first surface 230A of the substrate 230 and the third interlayer insulating film 210. Although not specifically shown, the second interlayer insulating film 220 may include a plurality of conductive layers and insulating layers.

The second interlayer insulating film 220 may include, for example, silicon oxide, silicon oxynitride, a low-k material having a lower dielectric constant than that of silicon oxide, or a combination thereof. However, embodiments of the present disclosure are not limited thereto.

The third interlayer insulating film 210 may be formed on the second interlayer insulating film 220. Although not shown specifically, the third interlayer insulating film 210 may include a plurality of conductive layers and insulating layers.

The third interlayer insulating film 210 may include, for example, silicon oxide, silicon oxynitride, a low-k material having a lower dielectric constant than that of silicon oxide, or a combination thereof. However, embodiments of the present disclosure are not limited thereto.

The third key pattern structure LK1 and LK2 may be disposed in the third interlayer insulating film 210. However, embodiments of the present disclosure are not limited thereto. The third key pattern structure LK1 and LK2 may be disposed in the second interlayer insulating film 220. The third key pattern structure LK1 and LK2 may be formed using at least one of a conductive layer and an insulating layer in the third interlayer insulating film 210. The third key pattern structure LK1 and LK2 may include an insulating material and/or a conductive material.

Thereafter, after the first stack structure ST1 of FIG. 16 has been turned upside down, the second stack structure ST2 of FIG. 17 may be bonded to the first stack structure ST1. Accordingly, the bonding structure ST of FIG. 3 may be formed.

In the third direction Z, the blocking pattern structure BP1 and BP2 may be disposed between the first key pattern structure UK1 and UK2 and the second key pattern structure LK1 and LK2.

The first key pattern structure UK1 and UK2, the second key pattern structure LK1 and LK2, and the blocking pattern structure BP1 and BP2 may overlap one another in the third direction Z.

That is, the first key pattern structure UK1 and UK2, the second key pattern structure LK1 and LK2, and the blocking pattern structure BP1 and BP2 may be disposed at the same position in each of the first horizontal direction X and the second horizontal direction Y.

According to some embodiments, the blocking pattern structure BP1 and BP2 may be formed between the first key pattern structure UK1 and UK2 and the second key pattern structure LK1 and LK2 in the scribe lane area 20. Accordingly, in a process for measuring the alignment keys and/or the overlay keys, the signal superimposition due to the key overlapping may be suppressed, thereby securing the reliability of the manufacturing process of the semiconductor device. In addition, the chip areas 10 in which the semiconductor memory elements are formed may be secured in a size as large as possible.

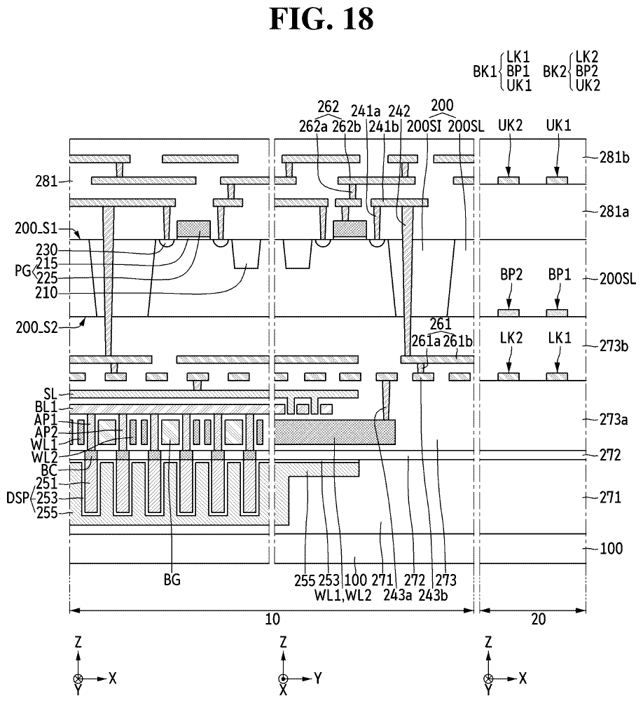

FIG. 18 is an example diagram for illustrating a semiconductor device according to some embodiments. For convenience of description, contents duplicate with those as described above with reference to FIGS. 1 to 17 will be briefly described or descriptions thereof will be omitted.

Referring to FIG. 18, the semiconductor device according to some embodiments may include the chip area 10 and the scribe lane area 20 around the first area 10. The chip area 10 may include a memory cell. The memory cell MC may include word lines WL1 and WL2 extending in the first direction Y, a bit line BL1 extending in the second direction X intersecting the first direction Y, and active patterns AP1 and AP2 connected to the bit line BL1, as described below.

The semiconductor device according to some embodiments may include a peripheral active substrate 200, a peripheral gate structure PG, a first connection wiring structure 261, a second connection wiring structure 262, a peripheral contact plug 241a, a peripheral wiring line 241b, and a peripheral connection through plug 242.

The substrate 100 may be a silicon substrate, or may include a material other than silicon, for example, silicon germanium, indium antimonide, lead telluride compound, indium arsenide, indium phosphide, gallium arsenide, or gallium antimonide. However, embodiments of the present disclosure are not limited thereto.

A data storage pattern DSP may be disposed on the substrate 100. Although not shown, the data storage patterns DSP may be arranged in a matrix form along the first direction Y and the second direction X.

For example, the third direction Z may be a thickness direction of the substrate 100. The first direction Y and the second direction X may be parallel to an upper surface of the substrate 100.

For example, the data storage patterns DSP may be a capacitor. The data storage patterns DSP may include a capacitor dielectric film 253 interposed between storage electrodes 251 and a plate electrode 255. In a plan view, the storage electrode 251 may have various shapes such as a circle, an ellipse, a rectangle, a square, a rhombus, and a hexagon.

Each of the storage electrode 251 and the plate electrode 255 may include, for example, at least one of a conductive semiconductor material, a conductive metal nitride, a conductive metal silicon nitride, a metal carbonitride, a conductive metal silicide, a conductive metal oxide, and a metal. The capacitor dielectric film 253 may include at least one of a ferroelectric material, an anti-ferroelectric material, and a paraelectric material. For example, the capacitor dielectric film 253 may include one of a ferroelectric material, an anti-ferroelectric material, a paraelectric material, a combination of a ferroelectric material and an anti-ferroelectric material, a combination of a ferroelectric material and a paraelectric material, a combination of a paraelectric material and an anti-ferroelectric material, a combination of a ferroelectric material, an anti-ferroelectric material, and a paraelectric material.

Alternatively, the data storage patterns DSP may be variable resistance patterns that may be switched to two resistance states by an electrical pulse applied to a memory element. For example, the data storage patterns DSP may include a phase-change material whose a crystal state changes depending on an amount of current, perovskite compounds, a transition metal oxide, magnetic materials, ferromagnetic materials, or antiferromagnetic materials.

Contact patterns BC may be disposed on the storage electrode 251. The contact patterns BC may be connected to a first active pattern AP 1 and a second active pattern AP 2, respectively. Each of the contact patterns BC may have various shapes such as a circle, an oval, a rectangle, a square, a rhombus, a hexagon, and the like, in a plan view.

The contact pattern BC may include a conductive material. The contact pattern BC may include, for example, at least one of doped polysilicon, conductive metal nitride, conductive metal silicon nitride, metal carbonitride, conductive metal silicide, conductive metal oxide, a two-dimensional material, and a metal.

The first active patterns AP1 and the second active patterns AP2 may be disposed on the data storage pattern DSP. The data storage patterns DSP may be disposed between the first active pattern AP 1 and the substrate 100. The data storage patterns DSP may be disposed between the second active pattern AP 1 and the substrate 100. The first active patterns AP 1 and the second active patterns AP 2 may be alternately arranged along the first direction DR1. Although not shown, the first and second active patterns AP1 and AP2 may be two-dimensionally arranged along the first direction DR1 and the second direction DR2.

For example, each of the first active pattern AP 1 and the second active pattern AP 2 may be made of a single crystal semiconductor material. In one example, each of the first active pattern AP 1 and the second active pattern AP 2 may be made of single crystalline silicon.

A back gate electrode BG may be disposed on the data storage pattern DSP. The back gate electrode BG may be disposed on the contact pattern BC. The data storage pattern DSP may be disposed between the back gate electrode BG and the substrate 100.

The back gate electrode BG may extend in the second direction X. The back gate electrodes BG may be spaced apart from one another in the first direction Y. The back gate electrodes BG may be spaced apart from one another by a predetermined distance.

Each back gate electrode BG may be disposed between the first active pattern AP 1 and the second active pattern AP 2 adjacent to one another in the first direction Y. In other words, the first active pattern AP 1 may be disposed on one side of each back gate electrode BG, and the second active pattern AP 2 may be disposed on the other side of each back gate electrode BG.

The first active pattern AP1 may be disposed between a first word line WL1 and the back gate electrode BG. The second active pattern AP2 may be disposed between a second word line WL2 and the back gate electrode BG. A pair of the first word line WL1 and the second word line WL2 may be disposed between the back gate electrodes BG adjacent to one another in the first direction X.

The back gate electrode BG may include a conductive material, and for example, may include at least one of doped polysilicon, conductive metal nitride, conductive metal silicon nitride, metal carbonitride, conductive metal silicide, conductive metal oxide, two-dimensional material, and metal.

Although not shown, a back gate insulating film may be disposed between the back gate electrode BG and the first active pattern AP 1 and between the back gate electrode BG and the second active pattern AP 2.

The first word line WL1 and the second word line WL2 may be disposed on the data storage pattern DSP. The first word line WL1 and the second word line WL2 may be disposed on the contact patterns BC. The data storage patterns DSP may be disposed between the first word line WL1 and the substrate 100. The data storage patterns DSP may be disposed between the second word line WL2 and the substrate 100.

Each of the first word line WL1 and the second word line WL2 may extend in the second direction X. The first word lines WL1 and the second word lines WL2 may be alternately arranged in the first direction Y.

The first word line WL1 and the second word line WL2 may be spaced apart from the bit line BL and the contact pattern BC in the third direction Z. The first word line WL1 and the second word line WL2 may be located between the bit line BL and the contact pattern BC.

Each of the first word line WL1 and the second word line WL2 may include a conductive material. Each of the first word line WL1 and the second word line WL2 may include, for example, at least one of doped polysilicon, conductive metal nitride, conductive metal silicon nitride, metal carbonitride, conductive metal silicide, conductive metal oxide, two-dimensional material, and metal.

Although not shown, a gate insulating film may be disposed between the first word line WL1 and the first active pattern AP1 and between the second word line WL2 and the second active pattern AP2.

The first bit line BL1 may be disposed on the first active pattern AP1 and the second active pattern AP2. The first bit line BL1 may be connected to the first active pattern AP1 and the second active pattern AP2.

The first bit line BL1 may be disposed on the back gate electrode BG, the first word line WL1, and the second word line WL2. The first bit line BL1 may extend in the first direction X and across the back gate electrode BG.

The first bit line BL 1 may include a conductive material, and may include, for example, at least one of doped polysilicon, conductive metal nitride, conductive metal silicon nitride, metal carbonitride, conductive metal silicide, conductive metal oxide, two-dimensional material, and metal.

A shielding conductive pattern SL may be disposed on the first bit line BL1. The first bit line BL1 may be disposed between the shielding conductive pattern SL and the first word line WL1. The first bit line BL1 may be disposed between the shielding conductive pattern SL and the second word line WL2.

For example, the shielding conductive pattern SL may include a shielding conductive plate and a plurality of shielding conductive protrusions. The shielding conductive plate may have a flat plate shape. The plurality of shielding conductive protrusions may protrude from the shielding conductive plate in the third direction Z. The shielding conductive protrusion may be disposed between the first bit lines BL 1 adjacent to one another in the second direction X.

The shielding conductive pattern SL may include a conductive material, and for example, may include at least one of a conductive metal nitride, a conductive metal silicon nitride, a metal carbonitride, a conductive metal silicide, a conductive metal oxide, a two-dimensional material, and a metal.

Unlike what is shown, the shielding conductive pattern SL may not include the flat plate-shaped shielding conductive plate. In this case, the shielding conductive pattern SL may include a plurality of shielding conductive protrusions having a line shape.

The data storage pattern DSP is illustrated as being disposed between the substrate 100 and the first bit line BL1. However, embodiments of the present disclosure are not limited thereto. Unlike the illustrated example, the data storage pattern DSP may be disposed between a peripheral active substrate 200 and the first bit line BL1. In this case, the first bit line BL1 may be disposed between the substrate 100 and the word line WL1 and WL2.

In the semiconductor device according to some embodiments, the first bit line BL1, the first word line WL1, and the second word line WL2 may be disposed between the substrate 100 and the peripheral active substrate 200.

A first lower insulating film 271, a second lower insulating film 272, and a third lower insulating film 273 may be sequentially disposed on the substrate 100. The data storage pattern DSP may be disposed in the first lower insulating film 271. The contact pattern BC may be disposed in the second lower insulating film 272. The first and second word lines WL1 and WL2, the first bit line BL1, and the shielding conductive pattern SL may be disposed in the third lower insulating film 273.

Each of the first lower insulating film 271, the second lower insulating film 272, and the third lower insulating film 273 may include an insulating material. Although each of the first lower insulating film 271, the second lower insulating film 272, and the third lower insulating film 273 is illustrated as being embodied as a single film, this is only for convenience of illustration, and embodiments of the present disclosure are not limited thereto.

A lower contact plug 243a and a lower wiring line 243b may be disposed in the third lower insulating film 273. The lower wiring line 243b may be disposed on the data storage pattern DSP, the first bit line BL1, the first word line WL1, and the second word line WL2.

The lower contact plug 243a may connect the lower wiring line 243b and the word line WL1 and WL2 to one another. The lower contact plug 243a may connect the lower wiring line 243b and the shielding conductive pattern SL to one another. Although not shown, the lower contact plug 243a may connect the lower wiring line 243b and the first bit line BL 1 to one another. In addition, the lower contact plug 243a may connect the lower wiring line 243b and the plate electrode 255 of the data storage pattern DSP to one another.

It is illustrated that the lower contact plug 243a and the lower wiring line 243b are different films. However, embodiments of the present disclosure are not limited thereto. A boundary between the lower contact plug 243a and the lower wiring line 243b may not be defined. Each of the lower contact plug 243a and the lower wiring line 243b includes a conductive material.

A first connection wiring structure 261 may be disposed on the lower wiring line 243b. The first connection wiring structure 261 may be connected to the lower wiring line 243b. The first connection wiring structure 261 may be disposed in the third lower insulating film 273.

The first connection wiring structure 261 may include a first connection wiring 261b and a first connection via 261a. Although the first connection wiring structure 261 is illustrated as including the first connection wiring 261b disposed at one metal level, this is only for convenience of illustration, and embodiments of the present disclosure are not limited thereto. Unlike the illustrated example, the first connection wiring structure 261 may include a plurality of first connection wirings 261b respectively disposed at different metal levels.

Each of the first connection wiring 261b and the first connection via 261a may include a conductive material. Although the first connection wiring 261b and the first connection via 261a are illustrated as being different films, embodiments of the present disclosure are not limited thereto.

The peripheral active substrate 200 may be disposed on the first connection wiring structure 261. The peripheral active substrate 200 may be spaced apart from the substrate 100 in the third direction Z. The first connection wiring structure 261 may be disposed between the substrate 100 and the peripheral active substrate 200.

The peripheral active substrate 200 includes a peripheral semiconductor film 200SL and a peripheral semiconductor isolation film 200SI. For example, the peripheral active substrate 200 may include a plurality of peripheral semiconductor isolation films 200SI.

The peripheral semiconductor film 200SL includes a semiconductor material. The peripheral semiconductor film 200SL may include, for example, silicon, silicon germanium, indium antimonide, lead telluride compound, indium arsenide, indium phosphide, gallium arsenide, or gallium antimonide. However, embodiments of the present disclosure are not limited thereto. In following descriptions, an example in which the peripheral semiconductor film 200SL is embodied as a silicon film including silicon will be described.

The peripheral semiconductor isolation film 200SI includes an insulating material. The peripheral semiconductor isolation film 200SI may include, for example, silicon oxide and/or silicon nitride. However, embodiments of the present disclosure are not limited thereto.

The peripheral active substrate 200 may include a first surface 200_S1 and a second surface 200_S2 opposite to one another in the third direction Z. The second surface 200_S2 of the peripheral active substrate may face the substrate 100 and the first connection wiring structure 261. Each of the first surface 200_S1 of the peripheral active substrate and the second surface 200_S2 of the peripheral active substrate includes the peripheral semiconductor film 200SL and the peripheral semiconductor isolation film 200SI. In other words, each of the first surface 200_S1 of the peripheral active substrate and the second surface 200_S2 of the peripheral active substrate may be defined by the peripheral semiconductor film 200SL and the peripheral semiconductor isolation film 200SI.

A peripheral gate structure PG may be disposed on the peripheral semiconductor film 200SL. The peripheral gate structure PG may be disposed on the first surface 200_S1 of the peripheral active substrate. The peripheral gate structure PG may be disposed on a first surface 200SL_S1 of the peripheral semiconductor film. The peripheral gate structure PG may be included in a sensing transistor, a transfer transistor, a driving transistor, etc.

The peripheral gate structure PG may include a peripheral gate insulating film 215 and a peripheral gate conductive film 225. The peripheral gate insulating film 215 may include a silicon oxide film, a silicon oxynitride film, a high-k insulating film having a higher dielectric constant than that of the silicon oxide film, or a combination thereof.

The peripheral gate conductive film 225 may include a conductive material. The peripheral gate conductive film 225 may include, for example, at least one of a doped semiconductor material, a conductive metal nitride, a conductive metal silicon nitride, a metal carbonitride, a conductive metal silicide, a conductive metal oxide, a two-dimensional material 2D material, and a metal. In the semiconductor memory element according to some embodiments, the two-dimensional material may be a metallic material and/or a semiconductor material. The two-dimensional material may include a two-dimensional allotrope or a two-dimensional compound, and may include, for example, at least one of graphene, molybdenum disulfide (MoS₂), molybdenum diselenide (MoSe₂), tungsten diselenide (WSe₂), tungsten disulfide (WS₂), etc. However, embodiments of the present disclosure are not limited thereto. That is, since the above-described two-dimensional materials are only listed by way of example, the two-dimensional material that may be included in the semiconductor memory device of the present disclosure is not limited to the above-described materials.

Although not shown, a peripheral gate spacer may be disposed on a sidewall of the peripheral gate structure PG. The peripheral gate spacer includes an insulating material. In addition, the peripheral gate structure PG may further include a peripheral gate mask pattern disposed on the peripheral gate conductive film 225. The peripheral gate mask pattern is made of an insulating material.

A peripheral source/drain area 230 may be disposed on each of both opposing sides of the peripheral gate structure PG. The peripheral source/drain area 230 may be formed in the peripheral semiconductor film 200SL.

For example, the peripheral source/drain area 230 may be an impurity doped area obtained by doping n-type or p-type impurity elements into the peripheral semiconductor film 200SL. In another example, the peripheral source/drain area 230 may include an epitaxial semiconductor pattern. The epitaxial semiconductor pattern may be formed using an epitaxial growth method. The epitaxial semiconductor pattern may contain a doped n-type or p-type impurity element. The n-type impurity element may include at least one of phosphorus (P), arsenic (As), antimony (Sb), and bismuth (Bi). The p-type impurity element may include at least one of boron (B) and gallium (Ga).

An upper insulating film 281 is disposed on the first surface 200_S1 of the peripheral active substrate. The upper insulating film 281 includes an insulating material. Although the upper insulating film 281 is illustrated as being embodied as a single film, this is only for convenience of illustration, and embodiments of the present disclosure are not limited thereto.

A peripheral contact plug 241a and a peripheral wiring line 241b may be disposed in the upper interlayer insulating film 281.

The peripheral contact plug 241a may be connected to the peripheral source/drain area 230. The peripheral contact plug 241a may be connected to the peripheral gate structure PG. The peripheral contact plug 241a may be connected to the peripheral gate conductive film 225 of the peripheral gate structure PG. For example, the peripheral contact plug 241a may extend through a peripheral etch stop film 205 so as to be connected to the peripheral source/drain area 230 and the peripheral gate conductive film 225.

The peripheral wiring line 241b may be disposed on the peripheral contact plug 241a and the peripheral gate structure PG. The peripheral wiring line 241b may be disposed on the first surface 200_S1 of the peripheral active substrate. The peripheral wiring line 241b is connected to the peripheral contact plug 241a. For example, the peripheral wiring line 241b may be a wiring line closest to the peripheral gate structure PG in the third direction DR.3.

The peripheral contact plug 241a and the peripheral wiring line 241b are illustrated as being different films. However, embodiments of the present disclosure are not limited thereto. A boundary between the peripheral contact plug 241a and the peripheral wiring line 241b may not be defined. Each of the peripheral contact plug 241a and the peripheral wiring line 241b includes a conductive material.

A peripheral connection through plug 242 may be disposed between the peripheral wiring line 241b and the first connection wiring structure 261. The peripheral connection through plug 242 may connect the peripheral wiring line 241b and the first connection wiring structure 261 to one another. For example, the peripheral connection through plug 242 may connect the peripheral wiring line 241b and the first connection wiring 261b to one another.

The peripheral connection through plug 242 may extend in the third direction Z. The peripheral connection through-plug 242 may extend through the peripheral etch stop film 205. The peripheral connection through plug 242 includes a conductive material.

A second connection wiring structure 262 may be disposed on the peripheral wiring line 241b. The second connection wiring structure 262 may be connected to the peripheral wiring line 241b. The second connection wiring structure 262 may be disposed in the upper insulating film 281.

The second connection wiring structure 262 may include a second connection wiring 262b and a second connection via 262a. Although the second connection wiring structure 262 is illustrated as including a plurality of second connection wirings 262b disposed at different metal levels, this is only for convenience of illustration, and embodiments of the present disclosure are not limited thereto.

Each of the second connection wiring 262b and the second connection via 262a may include a conductive material. The second connection wiring 262b and the second connection via 262a are illustrated as being different films. However, embodiments of the present disclosure are not limited thereto.

The scribe lane area 20 may include the key pattern structure BK1 and BK2 described with reference to FIGS. 1 to 17.

The key pattern structure BK1 and BK2 include the first key pattern structure LK1 and LK2, the second key pattern structure UK1 and UK2, and the blocking pattern structure BP1 and BP2.

The first key pattern structure LK1 and LK2 may be disposed on a (3_1)-th lower insulating film 273a. The first key pattern structure LK1 and LK2 may be disposed in a (3_2)-th lower insulating film 273b.

The second key pattern structure UK1 and UK2 may be disposed on the first key pattern structure LK1 and LK2. The second key pattern structure UK1 and UK2 may be disposed on a (1_1)-th upper insulating film 281a. The second key pattern structure UK1 and UK2 may be disposed in a (1_2)-th upper insulating film 281b.

The blocking pattern structure BP1 and BP2 may be disposed in the peripheral semiconductor film 200SL. The blocking pattern structure BP1 and BP2 may be disposed between the first key pattern structure LK1 and LK2 and the second key pattern structure UK1 and UK2 in the third direction Z. The first key pattern structure LK1 and LK2, the second key pattern structure UK1 and UK2, and the blocking pattern structure BP1 and BP2 may be disposed at the same position in each of the first direction Y and the second direction X. The width of the first key pattern structure LK1 and LK2, the width of the second key pattern structure UK1 and UK2, and the width of the blocking pattern structure BP1 and BP2 in each of the first direction Y and the second direction X may be equal to one another.

The blocking pattern structure BP1 and BP2 may include different materials. Although not shown specifically, the blocking pattern structure BP1 and BP2 may include the first pattern layer and the second pattern layer sequentially stacked. In this case, the first pattern layer may include carbon, and the second pattern layer may include metal.

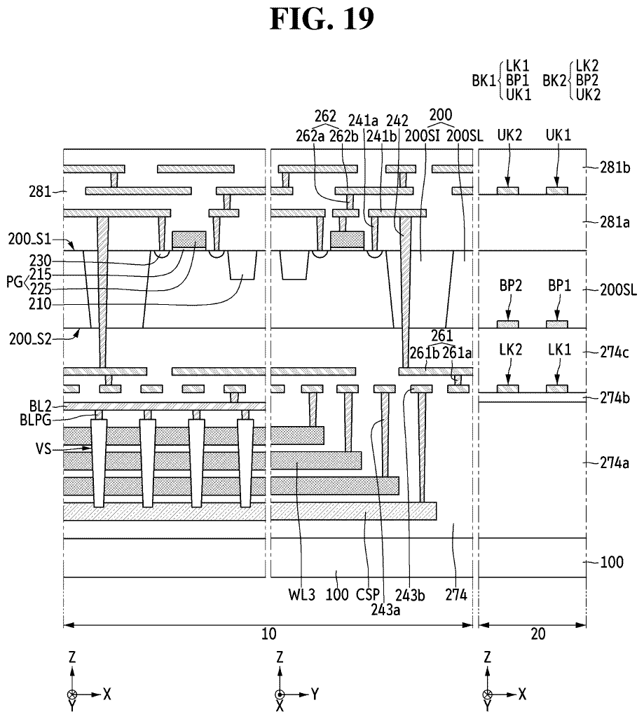

FIG. 19 is an example diagram for illustrating a semiconductor device according to some embodiments. For convenience of description, contents duplicate with those as described above using FIGS. 1 to 18 will be briefly described or descriptions thereof will be omitted.

Referring to FIG. 19, the semiconductor device according to some embodiments may include the chip area 10 and the scribe lane area 20 around the chip area 10. The chip area 10 may include a memory cell. The memory cell may include word lines WL3 respectively extending in the first direction Y, a bit line BL2 extending in the second direction X intersecting the first direction Y, and a memory channel structure VS connected to the bit line BL2.

The semiconductor device according to some embodiments may include a common source line CSP, the third word line WL3, the memory channel structure VS, and the second bit line BL2.

The common source line CSP may have a plate shape. The common source line CSP includes a conductive material.

The plurality of third word lines WL3 may be disposed on the common source line CSP. In a cross-sectional view taken in the second direction X, the third word lines WL 3 are arranged in a stepwise manner in the third direction Z. Each third word line WL3 may extend in the second direction X. The third word line WL3 includes a conductive material.

The memory channel structure VS may extend through the plurality of third word lines WL3. The memory channel structure VS may include a channel area and a charge storage area. The channel area of the memory channel structure VS may be electrically connected to the common source line CSP. The channel area of the memory channel structure VS may extend through the word lines WL3 in the third direction Z.

The second bit line BL2 may be disposed on the memory channel structure VS. The second bit line BL2 may extend in the first direction Y. The second bit line BL2 may be electrically connected to the channel area of the memory channel structure VS.

A bit line plug BLPG may be disposed between the second bit line BL2 and the memory channel structure VS. The bit line plug BLPG may connect the second bit line BL2 to the memory channel structure VS. Each of the second bit line BL2 and the bit line plug BLPG includes a conductive material.

A fourth lower insulating film 274 may be disposed on the substrate 100. The second bit line BL2 and the third word line WL3 may be disposed in the fourth lower insulating film 274.

The fourth lower insulating film 274 may include an insulating material. Although the fourth lower insulating film 274 is illustrated as being a single film, this is only for convenience of illustration, and embodiments of the present disclosure are not limited thereto.

The lower contact plug 243a may connect the lower wiring line 243b and the third word line WL3 to one another. The lower contact plug 243a may connect the lower wiring line 243b and the second bit line BL 2 to one another.

The lower contact plug 243a, the lower wiring line 243b, and the first connection wiring structure 261 may be disposed in the fourth lower insulating film 274.

The scribe lane area 20 may include the key pattern structure BK1 and BK2 described with reference to FIGS. 1 to 17.

The key pattern structure BK1 and BK2 include the first key pattern structure LK1 and LK2, the second key pattern structure UK1 and UK2, and the blocking pattern structure BP1 and BP2.

The first key pattern structure LK1 and LK2 may be disposed on (4_1)-th lower insulating film 274a and a (4_2)-th lower insulating film 274b. The first key pattern structure LK1 and LK2 may be disposed in a (4_3)-th lower insulating film 274c.

The second key pattern structure UK1 and UK2 may be disposed on the first key pattern structure LK1 and LK2. The second key pattern structure UK1 and UK2 may be disposed on a (1_1)-th upper insulating film 281a. The second key pattern structure UK1 and UK2 may be disposed in a (1_2)-th upper insulating film 281b.

The blocking pattern structure BP1 and BP2 may be disposed in the peripheral semiconductor film 200SL. The blocking pattern structure BP1 and BP2 may be disposed between the first key pattern structure LK1 and LK2 and the second key pattern structure UK1 and UK2 in the third direction Z. The first key pattern structure LK1 and LK2, the second key pattern structure UK1 and UK2, and the blocking pattern structure BP1 and BP2 may be disposed at the same position in each of the first direction Y and the second direction X. The width of the first key pattern structure LK1 and LK2, the width of the second key pattern structure UK1 and UK2, and the width of the blocking pattern structure BP1 and BP2 in each of the first direction Y and the second direction X may be equal to one another.

The blocking pattern structure BP1 and BP2 may include different materials. Although not shown specifically, the blocking pattern structure BP1 and BP2 may include the first pattern layer and the second pattern layer sequentially stacked. In this case, the first pattern layer may include carbon, and the second pattern layer may include metal.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A semiconductor device comprising:
a chip area and a scribe lane area;
a first substrate structure disposed in the scribe lane area and including a first key pattern structure;
a second substrate structure disposed in the scribe lane area and disposed on the first substrate structure, wherein the second substrate structure includes a second key pattern structure; and
a blocking pattern structure disposed in the scribe lane area and composed of different materials, wherein the blocking pattern structure is disposed between the first key pattern structure and the second key pattern structure in a vertical direction.

2. The semiconductor device of claim 1, wherein the first substrate structure extends in a first horizontal direction and a second horizontal direction intersecting one another,
wherein the first key pattern structure, the second key pattern structure, and the blocking pattern structure are disposed at a same position in each of the first horizontal direction and the second horizontal direction.

3. The semiconductor device of claim 1, wherein a width of the first key pattern structure, a width of the second key pattern structure, and a width of the blocking pattern structure are substantially equal to one another.

4. The semiconductor device of claim 1, wherein the blocking pattern structure includes a first pattern layer and a second pattern layer sequentially stacked.

5. The semiconductor device of claim 4, wherein a thickness of the first pattern layer is in a range of 2000 angstroms or greater,
wherein a thickness of the second pattern layer is in a range of 500 angstroms or greater.

6. The semiconductor device of claim 4, wherein the first pattern layer is in contact with a bottom surface and a sidewall of a recess defined in the first substrate structure,
wherein the second pattern layer is disposed in the recess and on the first pattern layer,
wherein a thickness in the vertical direction of the first pattern layer is greater than a thickness in the vertical direction of the second pattern layer.

7. The semiconductor device of claim 6, wherein the first pattern layer includes carbon, and the second pattern layer includes a metal.

8. The semiconductor device of claim 4, wherein the first pattern layer is in contact with a bottom surface and a sidewall of a recess defined in the first substrate structure,
wherein the second pattern layer is disposed in the recess and on the first pattern layer,
wherein a thickness in the vertical direction of the first pattern layer is smaller than a thickness in the vertical direction of the second pattern layer.

9. The semiconductor device of claim 8, wherein the first pattern layer includes a metal, and the second pattern layer includes carbon.

10. The semiconductor device of claim 1, wherein the second substrate structure further includes a third key pattern structure including a third pattern layer and a fourth pattern layer sequentially stacked,
wherein the third pattern layer and the fourth pattern layer include different materials.

11. The semiconductor device of claim 1, wherein the blocking pattern structure has a transmittance of light in a wavelength range of 400 nm to 900 nm in a range of 5% or smaller.

12. A semiconductor device comprising:
a chip area and a scribe lane area;
a first substrate structure disposed in the scribe lane area and including a first key pattern structure;
a blocking pattern structure disposed in a recess defined in the first substrate structure, wherein the blocking pattern structure includes a first pattern layer and a second pattern layer including different materials and sequentially stacked; and
a second substrate structure disposed in the scribe lane area and disposed on the first substrate structure, wherein the second substrate structure includes a second key pattern structure,
wherein the first key pattern structure, the second key pattern structure, and the blocking pattern structure overlap one another in a vertical direction.

13. The semiconductor device of claim 12, wherein the blocking pattern structure is disposed between the first key pattern structure and the second key pattern structure in the vertical direction.

14. The semiconductor device of claim 12, wherein the first pattern layer is in contact with a bottom surface and a sidewall of the recess,
wherein the second pattern layer is disposed in the recess and on the first pattern layer.

15. A semiconductor device comprising:
a first area including a memory cell;
a second area disposed around the first area and including a key pattern structure,
wherein the memory cell includes:
word lines extending in the first direction;
a bit line extending in a second direction intersecting the first direction; and
an active area connected to the bit line,
wherein the key pattern structure includes:
a first key pattern structure;
a second key pattern structure disposed on the first key pattern structure; and
a blocking pattern structure composed of different materials and disposed between the first key pattern structure and the second key pattern structure in a vertical direction.

16. The semiconductor device of claim 15, wherein the first key pattern structure, the second key pattern structure, and the blocking pattern structure are disposed at a same position in each of the first direction and the second direction.

17. The semiconductor device of claim 15, wherein a width of the first key pattern structure, a width of the second key pattern structure, and a width of the blocking pattern structure are substantially equal to one another.

18. The semiconductor device of claim 15, wherein the blocking pattern structure includes a first pattern layer and a second pattern layer sequentially stacked,
wherein the first pattern layer includes carbon, and the second pattern layer includes a metal.

19. The semiconductor device of claim 15, further comprising a data storage pattern disposed on the active area and connected to the active area.

20. The semiconductor device of claim 15, wherein the word lines are arranged in the vertical direction,
wherein the active area extends through the word lines in the vertical direction.
